(19) United States
(12) Patent Application Publication
(10) Pub. No.: US 2008/0020539 A1
(43) Pub. Date: Jan. 24, 2008

(54) DYNAMIC RANDOM ACCESS MEMORY AND FABRICATION METHOD THEREOF

(76) Inventors: CHIEN-KUO WANG, KEELUNG CITY (TW); JUN-CHI HUANG, DALI CITY (TW); RUEY-CHYR LEE, TAICHUNG CITY (TW); YUNG-CHANG LIN, TAICHUNG HSIEN (TW)

Correspondence Address: J.C. Patents, Suite 250, 4 Venture, Irvine, CA, 92618, US

(21) Appl. No.: 11/865,542

(22) Filed: Oct. 1, 2007

Related U.S. Application Data
(62) Division of application No. 11/437,081, filed on May 19, 2006.

(51) Int. Cl. H01L 21/02

(52) U.S. Cl. 438/386; 257/E21.008

(57) ABSTRACT

A dynamic random access memory including a substrate, an isolation structure, two transistors, two trench capacitors and two passing gates is provided. The isolation structure, including a first isolation structure and a second isolation structure, is disposed in the substrate. The second isolation structure is disposed in the substrate above the first isolation structure and the bottom surface of the second isolation structure is lower than the top surface of the substrate. The periphery of the second isolation structure is beyond that of the first isolation structure. The transistors are disposed on the substrate respectively at two sides of the isolation structure. The trench capacitors are respectively disposed between the transistors and the isolation structures. A portion of the second isolation structure is disposed in the trench capacitor. The passing gates are completely disposed on the second isolation structure.

### BACKGROUND OF THE INVENTION

1. Field of Invention

The present invention relates to a dynamic random access memory (DRAM) and the fabrication method thereof. More particularly, the present invention relates to a DRAM with efficient isolation between the passing gates and the trench capacitors, and the fabrication method thereof.

2. Description of Related Art

Dynamic random access memory (DRAM) stores data with capacitors. The data of each memory cell is determined by the electric charge of the capacitor thereof. For the small-size memory cells, the surface area of the capacitor bottom electrode is increased to provide sufficient storage capacitance, so as to reduce the chance of data misjudgment and reduce the refresh frequency of data for better operation efficiency. To meet the requirements for the large surface area of the capacitor and the integration of the memory cell, the trench capacitor has become the most popular option.

FIG. 1 is a cross-sectional view of a conventional dynamic random access memory (DRAM). In FIG. 1, to increase the integration of the DRAM in the circuit layout, two passing gates 102 are designed to pass over the top of the trench capacitor 104, and the passing gates 102 and the trench capacitor 104 are isolated by an isolation structure 106.

However, the isolation effect of the conventional isolation structure is not ideal because of large current leakage produced between the passing gates and the trench capacitor. In addition, since the width and the surface area of the conventional isolation structure are small, the process window for the subsequently formed passing gates and contact window is relatively small.

### SUMMARY OF THE INVENTION

Accordingly, the present invention is directed to provide a DRAM having an isolation structure which can provide efficient isolation between passing gates and trench capacitors.

According to another aspect of the present invention, a method for fabricating a trench capacitor with the isolation structure is provided, which can increase the process window for forming the passing gate and the contact window subsequently.

The present invention provides a dynamic random access memory structure, including a substrate, an isolation structure, two transistors, two trench capacitors and two passing gates. The isolation structure is disposed in the substrate and includes a first isolation structure and a second isolation structure disposed in the substrate above the first isolation structure. The bottom surface of the second isolation is lower than the top surface of the substrate, and a periphery of the second isolation structure is beyond that of the first isolation structure. The two transistors are disposed respectively on the substrate at two sides of the isolation structure. The two trench capacitors are disposed respectively between the transistors and the isolation structure. The two passing gate structures are disposed completely on the second isolation structure.

According to exemplary embodiments of the present invention, in the DRAM structure described above, the second isolation structure covers a portion of the two adjacent trench capacitors or the second isolation structure covers the two adjacent trench capacitors completely.

According to an exemplary embodiment of the present invention, two contact windows are included for connecting to the two corresponding trench capacitors. Each trench capacitor includes an upper electrode, a bottom electrode disposed in the substrate around the upper electrode and a capacitor dielectric layer disposed between the upper and bottom electrodes. The material of the capacitor dielectric layer is, for example, silicon oxide/silicon nitride/silicon oxide.

According to an exemplary embodiment of the present invention, the material of the first isolation structure is, for example, silicon oxide. The material of the second isolation structure is, for example, silicon oxide.

The present invention provides a method for fabricating a trench capacitor. First, a first isolation structure is formed in the substrate. Next, two trench capacitors are respectively formed in the substrate at two opposite sides of the first isolation structure. After that, a portion of the trench capacitors is removed to form an opening. Next, a second isolation structure is formed in the opening.

According to an exemplary embodiment of the present invention, the formation method of the opening comprises: forming a patterned mask layer on the substrate, exposing the trench capacitors; performing an etching process to the exposed trench capacitors; and removing the patterned mask layer.

According to an exemplary embodiment of the present invention, the etching process is, for example, anisotropic etching process.

According to an exemplary embodiment of the present invention, the formation method of the second isolation structure comprises: forming an insulation layer, which fills up the opening; and removing the insulation layer outside of the opening.

According to an exemplary embodiment of the present invention, the formation method of the insulation layer is, for example, chemical vapor deposition.

According to an exemplary embodiment of the present invention, the method of removing the insulation layer outside of the opening is, for example, chemical mechanical polishing.

According to the method for fabricating trench capacitor provided by the present invention, because the total thickness, width, and total surface area of the formed passing gate isolation structure are large, the passing gate isolation structure can effectively isolate two adjacent trench capacitors as well as the passing gate and the trench capacitor formed in subsequent processes, to prevent current leakage. In addition, since the isolation structure in the DRAM of the present invention has large width and surface area, the process window for forming the passing gate and the contact window can be accordingly increased.

In order to make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a conventional dynamic random access memory.

FIGS. 2A˜2H are cross-sectional views illustrating the fabricating process steps of a dynamic random access memory according to an embodiment of the present invention.

FIGS. 3A˜3G are cross-sectional views illustrating the fabricating process steps of a dynamic random access memory according to another embodiment of the present invention.

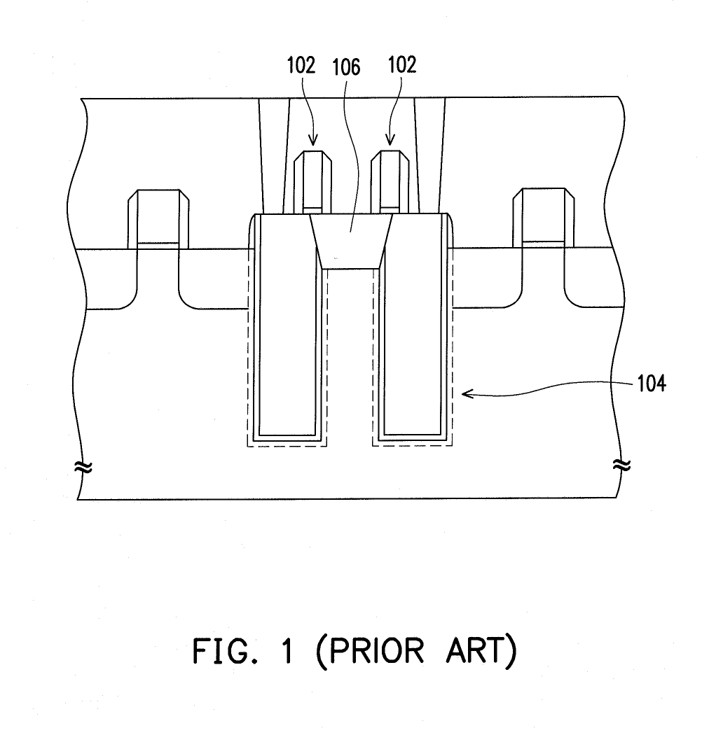

### DESCRIPTION OF EMBODIMENTS

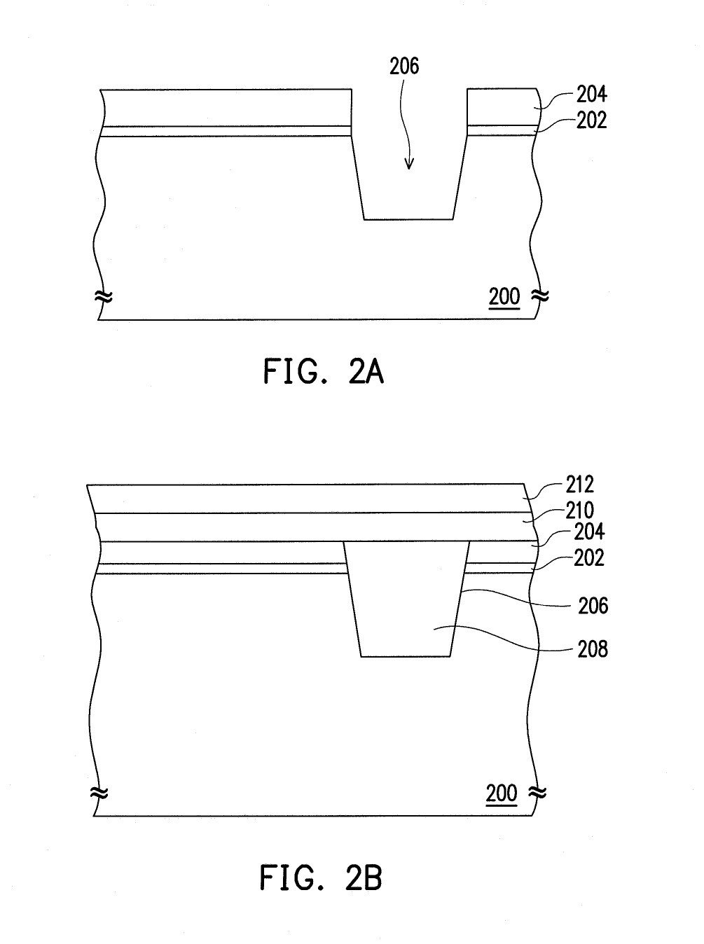

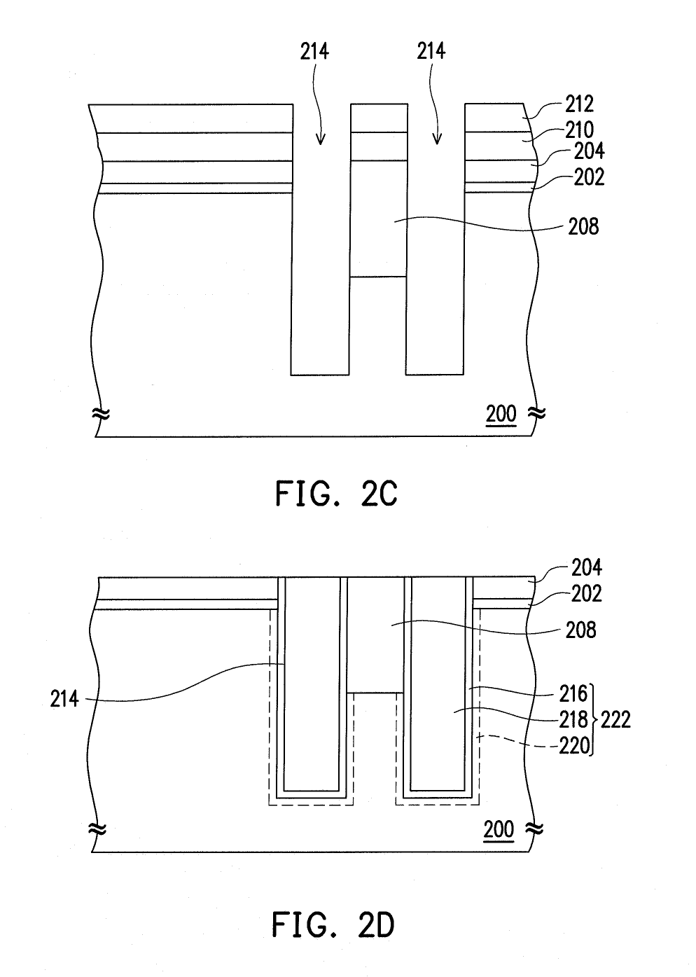

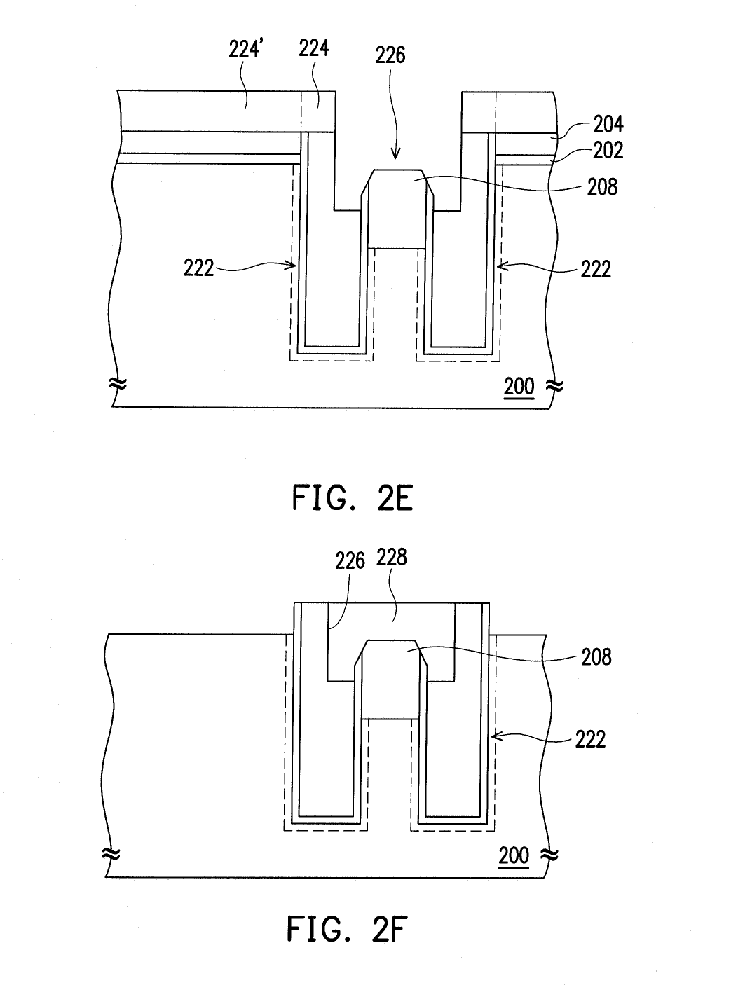

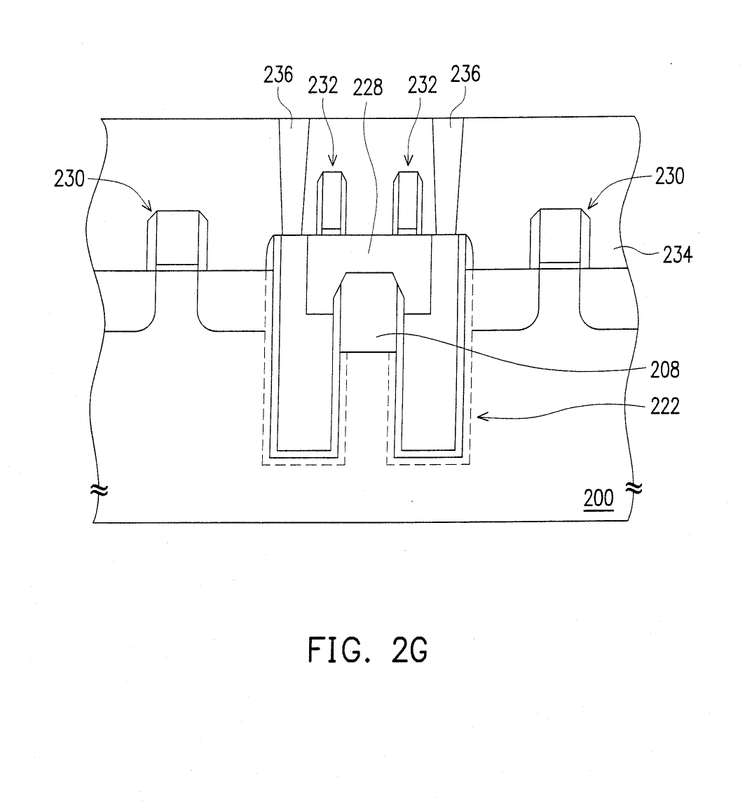

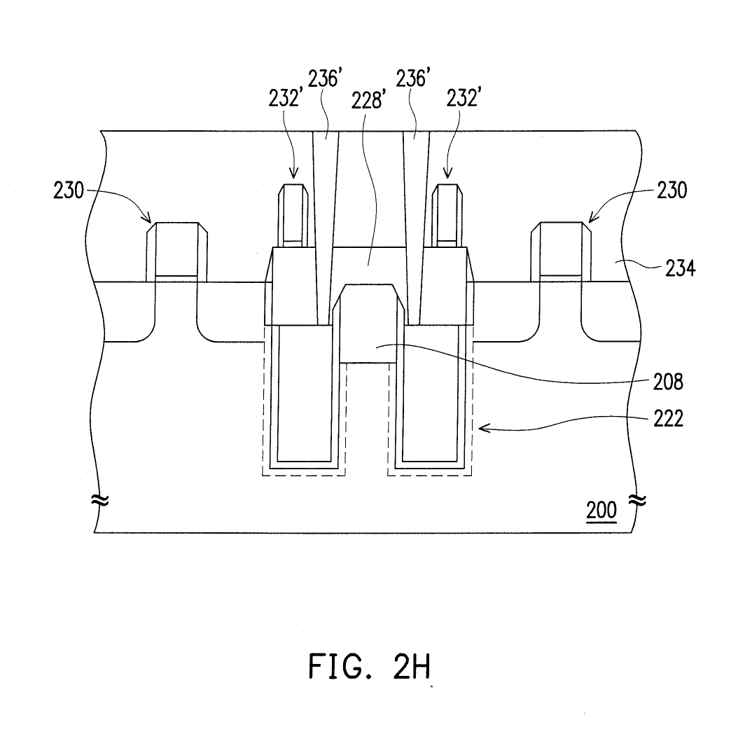

FIGS. 2A˜2H are cross-sectional views illustrating the fabricating process steps of a dynamic random access memory according to an embodiment of the present invention.

First, referring to FIG. 2A, a patterned pad oxide 202 and a patterned hard mask layer 204 are formed on the substrate 200 sequentially, and a portion of the substrate 200 is exposed. The substrate 200 is, for example, a silicon substrate. The material of the hard mask layer 204 is, for example, silicon nitride. Next, an etching process is performed to the substrate 200 using the hard mask layer 204 as the mask, to form a trench 206 in the substrate 200. The etching process performed to the substrate 200 is, for example, anisotropic etching process.

Then, referring to FIG. 2B, an insulation layer (not shown) is formed on the substrate 200 and the insulation layer fills up the trench 206. Next, a chemical mechanical polishing process is performed to the insulation layer by using the hard mask layer 204 as the polish stop layer, to form an isolation structure 208. The material of the isolation structure 208 is, for example, silicon oxide. After that, a dielectric layer 210 and a hard mask layer 212 are formed sequentially on the substrate 200. The material of the dielectric layer 210 is, for example, silicon nitride. The formation method of the dielectric layer 210 is, for example, chemical vapor deposition (CVD). The material of the hard mask layer 212 is, for example, polysilicon. The formation method of the hard mask layer 212 is, for example, chemical vapor deposition.

Next, referring to FIG. 2C, a patterning process is performed to the hard mask layer 212 to expose a portion of the dielectric layer 210. Next, a deep trench 214 is formed in the substrate 200 by using the hard mask layer 212 as the mask. The method of defining the deep trench 214 in the substrate 200 is, for example, performing a series of anisotropic etching processes using the hard mask layer 212 as the mask, and removing a portion of the dielectric layer 210, a portion of the hard mask layer 204, a portion of the isolation structure 208, a portion of the pad oxide 202, and a portion of the substrate 200 in sequence.

After that, referring to FIG. 2D, the hard mask layer 212 and the dielectric layer 210 are removed. Next, the trench capacitors 222 are formed in the substrate 200. The formation method of the trench capacitors 222 is, for example, forming a conformal dielectric layer 216 as the capacitor dielectric layer on the surface of the deep trench 214, then filling the conductive layer 218 in the deep trench 214 as the upper electrode. The inversion layer 220 in the substrate 200 around the deep trench 214 functions as the bottom electrode. The dielectric layer 216 is, for example, an oxide-nitride-oxide composite layer. The material of the conductive layer 218 is, for example, doped polysilicon.

Next, referring to FIG. 2E, a patterned mask layer 224, which exposes the isolation structure 208 and the trench capacitors 222, is formed over the substrate 200. The patterned mask layer 224 is, for example, a patterned photoresist layer. After that, an etching process is performed to the exposed trench capacitors 222 by using the patterned mask layer 224 as the mask, to remove a portion of the trench capacitors 222 to form the opening 226. The etching process performed to the exposed trench capacitors 222 is, for example, anisotropic etching process. In addition, in the process of removing a portion of the trench capacitors 222, a portion of the isolation structure 208 is removed simultaneously.

Then, referring to FIG. 2F, the patterned mask layer 224 is removed. Next, the isolation structure 228 is formed by filling up the opening 226. The material of the isolation structure 228 is, for example, silicon oxide. The formation method of the isolation structure 228 is, for example, first, forming an insulation layer (not shown) over the substrate 200 to fill up the opening 226, and then removing the insulation layer outside of the opening 226. The formation method of the insulation layer is, for example, chemical vapor deposition. The method of removing the insulation layer outside of the opening 226 is, for example, chemical mechanical polishing. After that, the hard mask layer 204 and the pad oxide 202 are removed to obtain the passing gate isolation structure consisting of the isolation structure 208 and the isolation structure 228 in the present embodiment.

Next, the following steps can be further executed to form a complete DRAM. Referring to FIG. 2G, the MOS transistors 230 electrically connected to the trench capacitors 222 are formed on the substrate 200 and the passing gates 232 are formed on the isolation structure 228. The formation methods of the MOS transistors 230 and the passing gates 232 are well-known to those with ordinary skills in the art, and will not be described herein again. Next, the dielectric layer 234 is formed over the substrate 200. Afterwards, the contact windows 236 connecting to the trench capacitors 222 are formed in the dielectric layer 234.

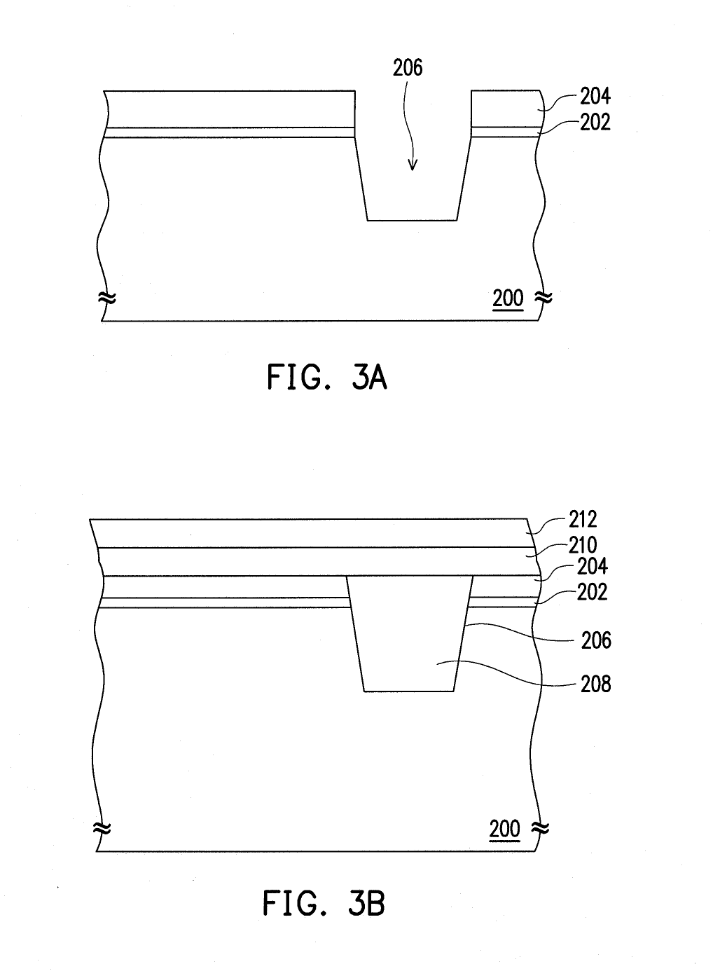

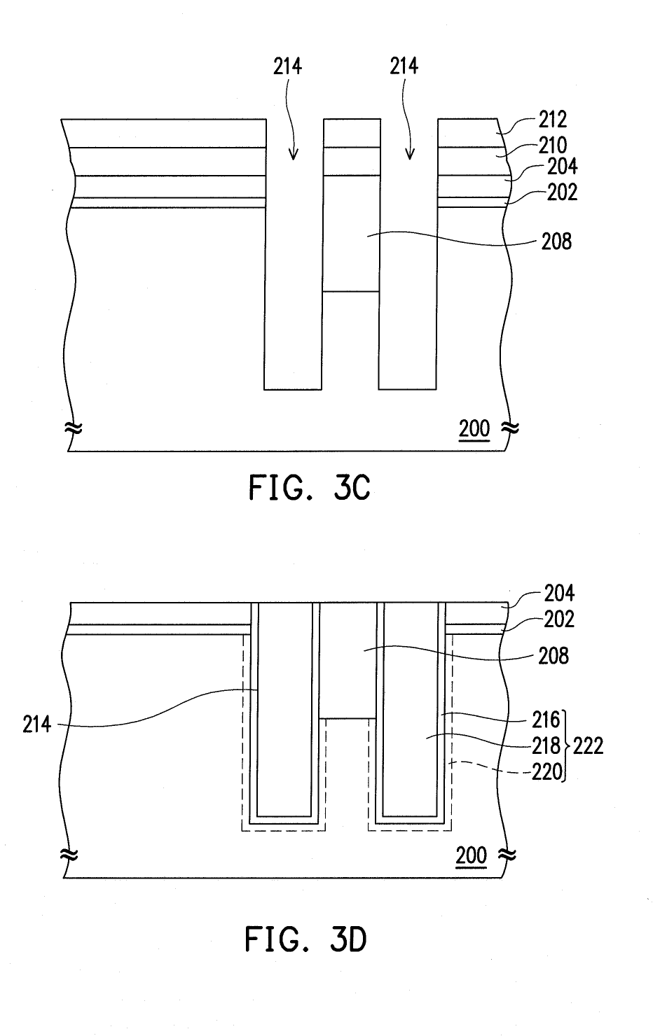

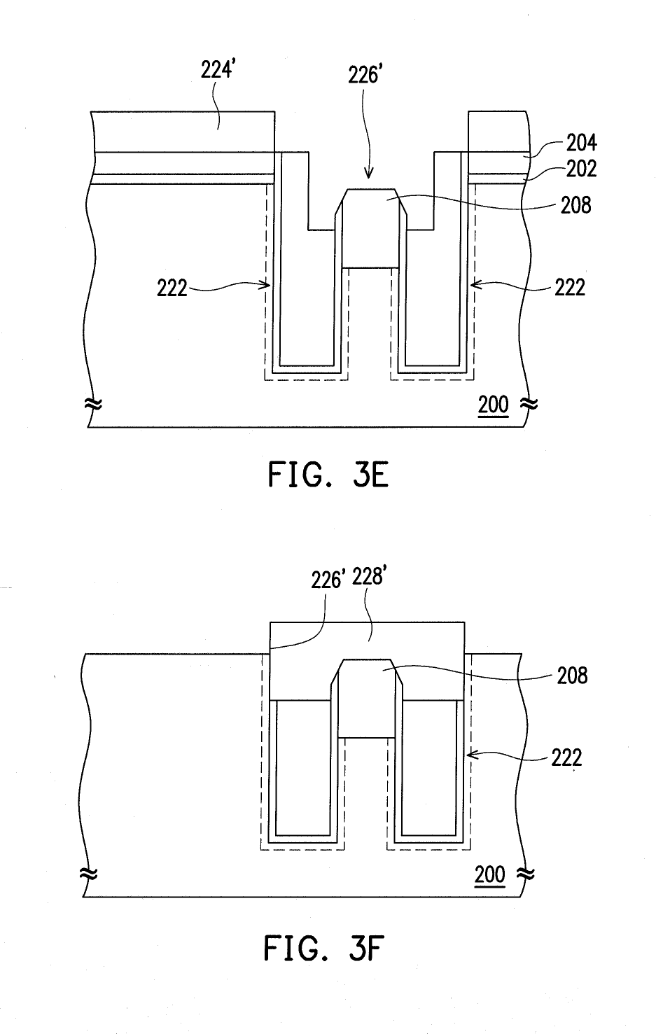

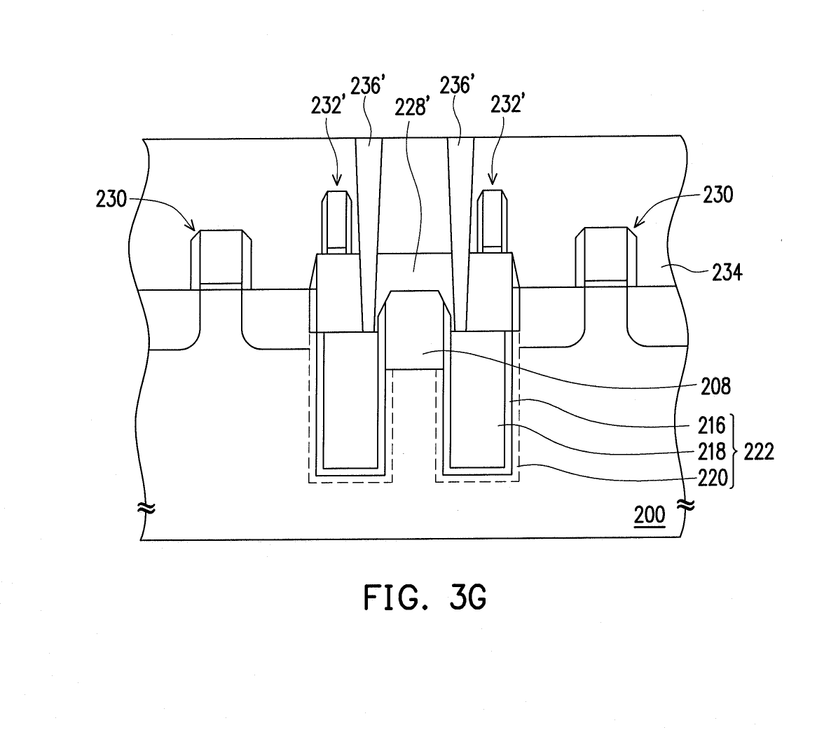

FIGS. 3A˜3G are cross-sectional views illustrating the fabricating process steps of a dynamic random access memory according to another embodiment of the present invention. The process steps of FIGS. 3A˜3D are substantially the same as the steps described in FIGS. 2A˜2D, and will not be described again in details.

Referring to FIG. 3E, a patterned mask layer 224′, which exposes the isolation structure 208 and the trench capacitors 222, is formed over the substrate 200. The patterned mask layer 224′ is, for example, a patterned photoresist layer. After that, an etching process is performed to the exposed trench capacitors 222 by using the patterned mask layer 224′ as the mask, to remove a portion of the trench capacitors 222 to form the opening 226′. The etching process performed to the exposed trench capacitors 222 is, for example, anisotropic etching process. In addition, in the process of removing a portion of the trench capacitors 222, a portion of the isolation structure 208 is removed simultaneously.

Then, referring to FIG. 3F, the patterned mask layer 224′ is removed. Next, the isolation structure 228′ is formed by filling up the opening 226′. The material of the isolation structure 228 is, for example, silicon oxide. The formation method of the isolation structure 228′ is, for example, first, forming an insulation layer (not shown) over the substrate 200 to fill up the opening 226′, and then removing the insulation layer outside of the opening 226′. The formation method of the insulation layer is, for example, chemical vapor deposition. The method of removing the insulation layer outside of the opening 226′ is, for example, chemical mechanical polishing. After that, the hard mask layer 204 and the pad oxide 202 are removed to obtain the passing gate isolation structure consisting of the isolation structure 208 and the isolation structure 228′ in the present embodiment.

Next, the following steps can be further executed to form a complete DRAM. Referring to FIG. 3G, the MOS transistors 230 electrically connected to the trench capacitors 222 are formed on the substrate 200 and the passing gates 232′ are formed on the isolation structure 228′. The formation methods of the MOS transistors 230 and the passing gates 232′ are well-known to those with ordinary skills in the art, and will not be described herein again. Next, the dielectric layer 234 is formed over the substrate 200. Afterwards, the contact windows 236 connecting to the trench capacitors 222 are formed in the dielectric layer 234.

Referring to FIGS. 2E, 2G, 3E and 3G, the main structural difference between the isolation structure 228′ and the isolation structure 228 is caused by the difference in the patterned mask layers used. The patterned mask layer 224 used to form the isolation structure 228 only exposes a portion of the trench capacitors 222, while the patterned mask layer 224′ used to form the isolation structure 228′ exposes the entire trench capacitors 222.

Since the passing gate isolation structure of the DRAM is formed from the isolation structure 208 and the isolation structure 228 (or 228′), it can effectively isolate the passing gates 232 (or 232′) and the trench capacitors 222 as well as isolating the two adjacent trench capacitors 222. Moreover, the process window for forming the passing gates 232, 232′ and the contact windows 236, 236′ can be increased effectively because the width and the surface area of the isolation structure are increased.

Referring to FIG. 2G, the DRAM includes the substrate 200, the isolation structures 208, 228, two transistors 230, two trench capacitors 222, two passing gates 232 and two contact windows 236.

The isolation structure 208 is disposed in the substrate 200, while the isolation structure 228 is disposed in the substrate 200 above the isolation structure 208 and the bottom surface of the isolation structure 228 is lower than the top surface of the substrate 200. The periphery of the isolation structure 228 is beyond the periphery of the isolation structure 208. The transistors 230 are disposed on the substrate 200 respectively at two sides of the isolation structure 228. The trench capacitors 222 are respectively disposed between the transistors 230 and the isolation structure 228. A portion of the isolation structure 228 is disposed within the trench capacitor 222. The trench capacitor 222 consists of the conductive layer 218 (as the upper electrode), the inversion layer 220 (as the bottom electrode) and the dielectric layer 216 (as the capacitor dielectric layer). The inversion layer 220 is disposed in the substrate 200 around the periphery of the conductive layer 218. The dielectric layer 216 is disposed between the inversion layer 220 and the conductive layer 218. The passing gates 232 are completely disposed on the isolation structure 228. The contact windows 236 are respectively connected to the corresponding trench capacitors 222. The material and formation method of the aforementioned elements of the DRAM have been explained above in details and will not be described again.

Since the isolation structure of the present invention is comprised of the isolation structure 208 and the isolation structure 228 (or 228′), so that besides, it can effectively isolate two adjacent trench capacitors 222 and also the passing gate 232 (or 232′) subsequently formed on the isolation structure 228 (or 228′) and the trench capacitors 222. Accordingly, the problem of current leakage between the passing gate and the trench capacitors 222 can be avoided.

In conclusion, the present invention has at least the following advantages:

1. According to the method of the present invention, the process window for forming the passing gate and the contact window in subsequent process can be increased effectively.

2. The passing gate isolation structure of the DRAM in the present invention can effectively isolate the trench capacitors and the passing gates formed on the isolation structure in the subsequent process.

3. Owning to the passing gate isolation structure in the DRAM of the present invention, the current leakage produced between the passing gate and the trench capacitors can be avoided.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1-8. (canceled)

9. A method for fabricating trench capacitor, comprising:
forming a first isolation structure in a substrate;
forming a trench capacitor in the substrate at each of both sides of the first isolation structure;
removing a portion of the trench capacitors to form an opening; and
forming a second isolation structure which fills up the opening.

10. The fabricating method as claimed in claim 9, wherein the formation method of the opening comprises:
forming a patterned mask layer on the substrate, exposing the trench capacitors;
performing an etching process to the exposed trench capacitors; and
removing the patterned mask layer.

11. The fabricating method as claimed in claim 10, wherein the etching process includes an anisotropic etching process.

12. The fabricating method as claimed in claim 10, wherein the patterned mask layer includes a patterned photoresist layer.

13. The fabricating method as claimed in claim 9, wherein the formation method of the second isolation structure comprises:
forming an insulation layer over the substrate to fill up the opening; and
removing the insulation layer outside of the opening.

14. The fabricating method as claimed in claim 13, wherein the formation method of the insulation layer includes chemical vapor deposition.

15. The fabricating method as claimed in claim 13, wherein the method of removing the insulation layer outside of the opening includes chemical mechanical polishing.
